(19) United States
(12) Patent Application Publication
(10) Pub. No.: US 2015/0095866 A1
(43) Pub. Date: Apr. 2, 2015

(54) VLSI CIRCUIT SIGNAL COMPRESSION

(71) Applicant: Cigol Digital Systems Ltd., Yokneam (IL)

(72) Inventors: Gilad Cohen, Rehovot (IL); Avi Rabinovich, Kiryat Motzkin (IL); Nadav Cohen, Yavne (IL); Tomer Labin, Haifa (IL); Noam Petrank, Tel Aviv (IL)

(21) Appl. No.: 14/383,597

(22) PCT Filed: Mar. 11, 2013
(86) PCT No.: PCT/IB2013/051906

§ 371 Date: Sep. 8, 2014

Related U.S. Application Data
(60) Provisional application No. 61/609,328, filed on Mar. 11, 2012.

(51) Int. Cl. G06F 17/50; H01L 27/02

(52) U.S. Cl. CPC G06F 17/5081; H01L 27/0207; G06F 17/5054
USPC 716/113; 716/117

(57) ABSTRACT

An embedded agent (104) of an integrated circuit (102) includes a collector (220) configured to receive from a tested target circuit a plurality of single bit lines of signals and a signal canceller (322) configured to receive an indication of lines that are not to be exported, for a given time period, and to set the indicated lines to a constant value. A linear combination calculation circuit (402) configured to generate a plurality of different linear combinations of the values of the single bit lines, for the clock cycles of the given time period, is also included in the embedded agent. A transmitter (216) exports from the chip a sub-group of the linear combinations calculated by the linear combination calculation circuit for the clock cycles of the given time period, the sub-group including a number of linear combinations selected responsively to the number of lines set to a constant value.

### CROSS-REFERENCE TO RELATED APPLICATION

This application claims the benefit under 35 USC 119(e) of U.S. Provisional Patent Application 61/609,328, filed Mar. 11, 2012, which is incorporated herein by reference.

### FIELD OF THE INVENTION

The present invention relates generally to integrated circuits and particularly to design verification of integrated circuits.

### BACKGROUND OF THE INVENTION

Integrated circuits have become very complex, sometimes including millions of transistors in a single integrated circuit (IC). Field programmable gate arrays (FPGA) are integrated circuits including a large number of transistors which the user can configure to perform a desired task by adjusting the connections between the transistors. An FPGA can be reconfigured repeatedly, allowing a user to test the operation of the FPGA and correct errors. Users generally define a required circuit design in a hardware definition language (HDL) and a compiler converts the user design into a layout which is then configured into the FPGA.

Integrated circuits use various methods in order to communicate with external units.

U.S. Pat. No. 7,187,709 to Menon et al., describes a high-speed configurable transceiver architecture.

U.S. Pat. No. 7,751,442 to Chang et al. describes using a serial Ethernet device to device interconnection.

U.S. Pat. No. 7,500,060 describes using a hardware stack for communication with an FPGA based embedded processor system on chip (SoC).

Due to their complexity it is important to verify correctness of the design of integrated circuits.

US patent publication 2008/0270953 to Foreman et al. describes methods for evaluating an IC chip including running a statistical static timing analysis (SSTA).

A product specification of Xilinx, dated Apr. 19, 2010, relating to Chipscope Pro Integrated Logic Analyzer describes an integrated logic analyzer (ILA) which can be used to monitor any internal signal in a designed FPGA. The ILA comprises a core embedded in the FPGA with the user's logic. The embedded core of the ILA includes a large buffer in which monitored signals are stored. After the buffer is filled, the stored signals are uploaded to ILA software.

U.S. Pat. No. 6,760,898 describes inserting probe points in an FPGA system on chip.

US patent publication 2012/0011411, titled “On-Chip Service Processor” describes embedding a service processor unit (SPU) into a tested integrated circuit. The SPU may set values in the user logic and collects monitored signals in a buffer at the rate of the user logic. The Stored signals from the buffer are exported at an external clock rate.

U.S. Pat. No. 7,882,465 to Li et al., titled: “FPGA and Method and System for configuring and Debugging a FPGA”, describes an FPGA with a probe signal selection unit and a high speed serial transceiver configured to transmit a probed signal to an external unit.

U.S. Pat. No. 7,533,315 to Han et al. describes an integrated circuit with scan based debugging.

U.S. Pat. No. 6,985,848 to Swoboda et al. describes exporting on-chip trace and timing information using a sign extension compression or a compression map.

U.S. Pat. No. 8,099,273 to Selvidge et al. describes exporting emulation trace data using delta compression.

U.S. Pat. No. 7,814,444 to Wohl et al. describes using combinatorial compression using XOR gates.

U.S. Pat. No. 6,950,974 to Wohl et al. describes a compression of deterministic patterns.

U.S. Pat. No. 6,829,740 to Rajski et al. describes using linear spatial compactors.

### SUMMARY

Embodiments of the present invention that are described hereinbelow provide methods and systems for statistical analysis of signals of integrated circuits. Further embodiments describe a method for compression of monitored signals exported from an integrated circuit and/or injected into an integrated circuit.

There is therefore provided in accordance with an embodiment of the present invention an integrated circuit, comprising a target circuit on a chip; and an embedded agent on the chip, including a signal collector configured to collect from the target circuit a plurality of single bit lines of signals, a signal canceller configured to receive an indication of lines that are not to be exported, for a given time period, and to set the indicated lines to a constant value, for the given time period, a linear combination calculation circuit configured to generate a plurality of different linear combinations of the values of the single bit lines, for the clock cycles of the given time period and a transmitter configured to export from the chip a sub-group of the linear combinations calculated by the linear combination calculation circuit for the clock cycles of the given time period, the sub-group including a number of linear combinations selected responsively to the number of lines set to a constant value.

Optionally, the signal canceller comprises an array of AND gates. Optionally, the signal collector comprises a register or latch. The linear combination calculation circuit optionally includes XOR gates which calculate the linear combinations.

Optionally, the linear combination calculation circuit calculates at least one linear combination from signals of a plurality of clock cycles.

Optionally, transmitter is configured to export a predetermined number of linear combinations calculated from bits of a plurality of different clock cycles and a variable number of linear combinations that each depend on bits of a single clock cycle. Optionally, the linear combination calculation circuit calculates most of the linear combinations it calculates from signals of a single clock cycle. Optionally, the embedded agent comprises a circuit which determines whether the signals on the single bit lines changed and indicates the lines that did not change during the given time period for setting to a constant value. Optionally, the embedded agent receives indication of the signals to be set to a constant value from outside the chip. Optionally, the linear combination calculation circuit is configured to generate each of the different linear combinations from between 40% to 60% of the single bit lines. Optionally, a plurality of the single bit lines belong to a single multi-bit bus. Optionally, the embedded agent is further configured to generate and export a mask which indicates the lines that were set to a constant value, for the given time period.

There is further provided in accordance with an embodiment of the present invention, a method of exporting a selected sub-group of signals from an integrated circuit, including collecting, by a signal exporting circuit on a chip, signals of a plurality of single bit lines, receiving an indication of lines that are not to be exported, for a given time period, and setting the values of the lines during the given time period to a constant value, by the signal exporting circuit, calculating a plurality of different linear combinations of the values of the single bit lines, for the clock cycles of the given time period; and exporting from the chip a sub-group of the calculated linear combinations, the sub-group including a number of linear combinations selected responsively to the number of lines set to a constant value.

Optionally, collecting the signals of the plurality of single bit lines comprises sampling signals from one or more internal lines of an integrated circuit, for debugging or testing. Optionally, the method includes generating and exporting a mask which indicates the lines that were set to a constant value, for the given time period.

Optionally, the method includes exporting the collected signals for one of the cycles of the given time period. Optionally, at least one of the exported linear combinations is calculated from bits of a plurality of different clock cycles. In some embodiments, the exported linear combinations comprise a predetermined number of linear combinations calculated from bits of a plurality of different clock cycles and a variable number of linear combinations that each depend on bits of a single clock cycle. Optionally, the method includes receiving the exported calculated linear combinations by a computer and reconstructing the signals of the single bit lines from the exported calculated linear combinations by the computer. Optionally, the method includes determining whether the signals on the single bit lines changed and indicating the lines that did not change as the lines that are not to be exported. Optionally, the indication of the lines that are not to be exported is received from outside the chip.

There is further provided in accordance with an embodiment of the present invention, a method of receiving data from a chip, including configuring a computer with the details of linear combinations generated by a signal exporting circuit on a chip, receiving, at the computer, linear combinations generated by the chip from signals on a plurality of lines during a given time period, a mask indicative of lines that were set to constant values during the time period, and reconstructing by the computer of the signals on the lines that were not set to a constant value for the given time period, by reversing the linear combinations.

Optionally, the method includes receiving by the computer the values on the lines in one of the clock cycles of the given time period and reconstructing the values on the lines that were set to a constant value as the value in the one clock cycle, for the entire given time period.

There is further provided in accordance with an embodiment of the present invention, a method of analyzing operation of an integrated circuit, including collecting signals from a plurality of internal lines of the integrated circuit, determining, by a processor, a plurality of time points at which an event occurred, responsive to signals from one or more of the internal lines, selecting a plurality of time points at which the event did not occur, extracting, for time windows in the vicinity of the determined and selected time points, respective signal windows from one or more of the lines from which signals were collected; and determining, by the processor, a statistically significant difference between signal windows corresponding to occurrence of the event and signal windows not corresponding to the event, for at least one of the lines.

Optionally, determining, by the processor, a plurality of time points at which an event occurred comprises determining time points at which interrupts occurred.

Optionally, determining the statistically significant difference comprises calculating a descriptor for each of the windows and determining a statistically significant difference in the value of the descriptor.

Optionally, the descriptor comprises a throughput, a packet length, a signal latency and/or a period between packets.

There is further provided in accordance with an embodiment of the present invention, a method of analyzing operation of an integrated circuit on a chip, comprising providing a test input to a tested integrated circuit on a chip, repeatedly for a plurality of operation rounds, sampling signals from a plurality of internal lines of the tested integrated circuit, generating by a signature circuit on the chip, respective signatures for the plurality of internal lines, verifying, by the signature circuit, that the signature of the plurality of internal lines is the same for the plurality of operation rounds, and exporting from the chip in each operation round, the signals of one or more of the internal lines, but fewer than all the sampled lines.

Optionally, sampling the signals comprises sampling at a rate at least equal to the operation rate of the chip for the sampled signals. Optionally, the method includes receiving the exported signals of the plurality of operation rounds by a computer and displaying the signals as if they were received from a single operation round. Optionally, the method includes exporting the test input through a path used for exporting non-intrusively collected data, in a preliminary operation round, and wherein providing the test input to the tested integrated circuit comprises providing the data exported through the path used for exporting non-intrusively collected data. Optionally, the signature comprises a cyclically redundancy check code or a checksum.

There is further provided in accordance with an embodiment of the present invention, a method of generating a chip with a tested circuit and an embedded agent for non-intrusive export of internal signals of the tested chip, including providing a design of the tested circuit, providing a design of the embedded agent, selecting locations on the chip for the tested circuit and the embedded agent in a manner which reduces interference of the embedded agent to the operation of the tested circuit, designing a line connecting a sampling point in the tested circuit to a receiver of the embedded agent, the line including a cascade of one or more asynchronous gates which add a delay to the line, such that signals sampled at the sampling point reach the receiver a predetermined number of clock cycles after their sampling, and generating a chip with the provided designs of the tested circuit and embedded agent in the selected locations and with the designed line.

Optionally, the selected location of the embedded agent is separate from the tested circuit, such that elements of the embedded agent are not located between elements of the tested circuit.

Optionally, the designed line does not include synchronous elements between the sampling point and the receiver in the embedded agent.

Optionally, the cascade of asynchronous gates includes NOT gates and/or includes a plurality of gates, for example at least three gates or even at least five gates.

### BRIEF DESCRIPTION OF THE DRAWINGS

FIG. 1 is a schematic block diagram of a Field Programmable Gate Array (FPGA) verification system, in accordance with an embodiment of the invention;

FIG. 2 is a schematic illustration of a target FPGA with an emphasis on an embedded agent therein, in accordance with an embodiment of the invention;

FIG. 3 is a schematic block diagram of a collector, which compresses collected signals, in accordance with an embodiment of the invention;

FIG. 4 is a schematic block diagram of an arbiter included in an FPGA for data output, in accordance with an embodiment of the invention;

FIG. 5 is a schematic block diagram of an arrangement for repeated testing of a target circuit, in accordance with an embodiment of the invention;

FIG. 6 is a flowchart of acts performed by in analyzing the signals, in accordance with an embodiment of the invention;

FIG. 7 is a schematic illustration of selection of event and non-event windows on a plurality of lines monitored for on-chip statistical analysis, in accordance with an embodiment of the invention; and

FIG. 8 is a schematic illustration of a connection between a collection point and a collect register, in accordance with an embodiment of the invention.

### DETAILED DESCRIPTION OF EMBODIMENTS

An aspect of some embodiments of the invention relates to a method of exporting selected signals from a chip, by a signal exporting circuit, such as an embedded agent. The method includes setting to a constant value (e.g., 0), the signals that are not to be exported, calculating a plurality of different predetermined linear combinations of the bits of each output word that need to be output and selecting a number of linear combinations to be output, based on the number of bits that are to be output. A receiving computer reconstructs the original values from the exported linear combinations, using methods known in the art.

In some embodiments, the method is used for compression purposes. For each predetermined time block, the signals that did not change are determined and these signals are set to a constant value. Along with the exported linear combinations, the signal exporting circuit optionally exports a mask indicating the signals that did not change and their original values. The on-chip embedded core is optionally configured to compress data which is not known in advance, such that the compression unit is adapted to handle any sequence of data which it receives.

In other embodiments, the method is used as an implementation of an arbiter or multiplexer. The user or a selection program or circuit indicates to the signal exporting circuit which lines are to be exported and the remaining signals are set to a constant value.

Optionally, one or more of the linear combinations are calculated from bits of a plurality of different clock cycles in the time block. Using linear combinations of bits from different clock cycles adds to the probability that the data will be re-constructible, and is therefore advantageous although adding slightly to the complexity of the signal exporting circuit.

An aspect of some embodiments of the invention relates to a method of analyzing an integrated circuit, in which the signals from one or more internal lines of the integrated circuit are collected for a plurality of time windows in which an event occurred (or close to occurrence of the event) and a plurality of time windows in which the event did not occur (or not close to occurrence of the event). The signals in the time windows are compared to find statistically significant differences between the different types of time windows. These differences in the signals are optionally displayed to an operator, for example, to aid in determining the cause of the event.

An aspect of some embodiments of the invention relates to a method of non-intrusive signal collection and output from an on-chip circuit under test, in which the same input signals are provided to a circuit under test in a plurality of operation rounds, and in each round a different fraction of non-intrusively collected data is output from the chip. A computer receiving the signals outputted from the chip, optionally displays them as if they were collected in a single operation round of the circuit under test. Optionally, an on-chip embedded agent which performs the non-intrusive signal collection includes a signature generation module which generates a signature for portions of the collected data in different operation rounds and verifies that the signatures are the same in different operation rounds.

In some embodiments of the invention, the embedded agent is configured to output the input to the circuit under test, through a path used for export of the non-intrusively collected data, and to receive the data from an external storage and apply the data to an input line of the circuit under test in subsequent operation rounds.

An aspect of some embodiments of the invention relates to a method of generating an on-chip circuit for testing with an embedded agent for collecting and exporting signals from the tested circuit. The embedded agent is placed on a side of the chip separate from the tested circuit, so as not to interfere with the operation of the tested circuit by placing elements of the embedded agent between elements of the tested circuit, in a manner which may require using a slower clock. For signals collected by the embedded agent which originate at points far from the embedded agent, the line connecting the sampling point to the embedded agent is planned with an intended delay of one or more clock cycles, so that the collected signals reach a register of the embedded agent, a predetermined number of cycles after their sampling time. The intended delay is optionally implemented by an asynchronous shift register and/or by a cascade of not gates. The use of asynchronous elements to implement the delay makes the circuit simpler than if registers or other synchronous elements are used.

### System Overview

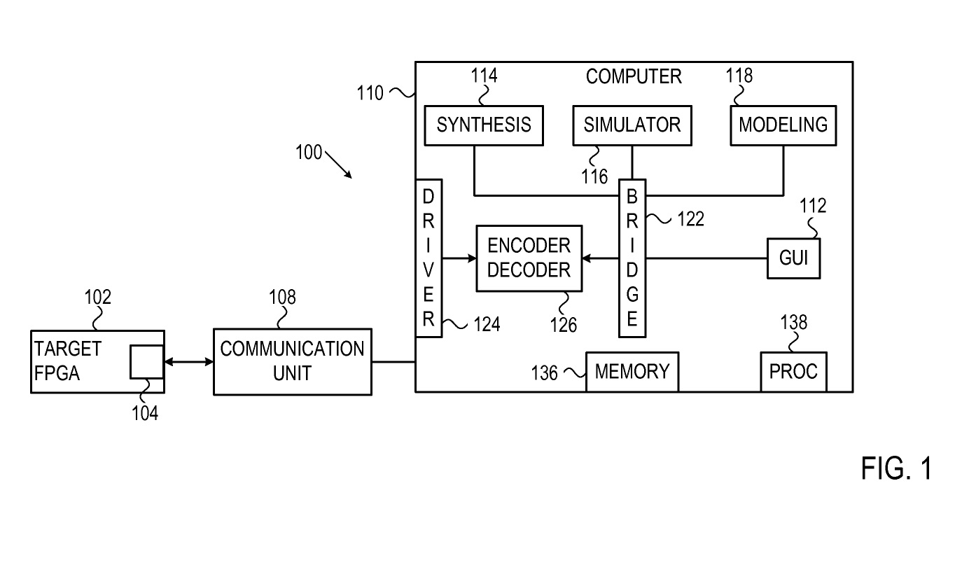

FIG. 1 is a schematic block diagram of a Field Programmable Gate Array (FPGA) verification system 100, in accordance with an embodiment of the invention. System 100 includes a target circuit such as a target FPGA 102 which is tested analyzed or debugged (also referred to herein as a tested circuit or a circuit under test), a computer 110 which serves as a work station for management of the verification and an intermediate communication unit 108, which handles communications between target FPGA 102 and computer 110. An embedded agent 104, or other signal exporting circuit, is included in the target FPGA 102. The embedded agent optionally collects signals from points of interest in the target FPGA 102, compresses them and transmits them toward communication unit 108. In some embodiments, embedded agent 104 also receives drive signals from computer 110, through communication unit 108, decompresses them and places the drive signals at indicated points in the verified target 102.

Computer 110 is optionally configured with a graphic user interface (GUI) 112 through which a user controls the verification of target FPGA 102. The user may use GUI 112 to define drive and collection points in the integrated circuit and parameters of the embedded agent 104, such as its reliability and/or transmission bandwidth.

Computer 110 is optionally also configured with one or more verification and handling tools, such as a synthesis tool 114, a simulator 116 (e.g., an RTL simulator, a ModelSim tool, Matlab) and/or a modeling tool 118. These tools receive signals collected from target FPGA 102 and accordingly analyze its operation. The tools may also be used to generate drive signals for the analysis. Optionally, the verification is performed using one or more tools used during the design of target FPGA 102, allowing the verification to be performed as a natural continuation of the design and RTL testing.

Computer 110 is optionally configured with a bridge 122 and a driver 124 for communication with embedded agent 104. In some embodiments of the invention, computer 110 is configured with an encoder and/or decoder unit 126, which encodes and/or decodes signals exchanged with embedded agent 104.

Computer 110 typically comprises a general-purpose computer or a cluster of such computers, with suitable interfaces, one or more processors 138, and software for carrying out the functions that are described herein, stored, for example, in a memory 136. The software may be downloaded to computer 110 in electronic form, over a network, for example. Alternatively or additionally, the software may be held on tangible, non-transitory storage media, such as optical, magnetic, or electronic memory media. Further alternatively or additionally, at least some of the functions of computer 110 may be performed by dedicated or programmable hardware logic circuits. For the sake of simplicity and clarity, only those elements of computer 110 that are essential to an understanding of the present invention are shown in the figures.

The details of system 100 not discussed herein may be as described in any of the embodiments of PCT publication WO 2012/164452, US patent publication 2012/0011411, U.S. Pat. No. 7,882,465 to Li et al., U.S. Pat. No. 7,533,315 to Han et al. the disclosures of which are incorporated herein by reference in their entirety, or in accordance with any suitable equivalents known in the art.

### Embedded Agent

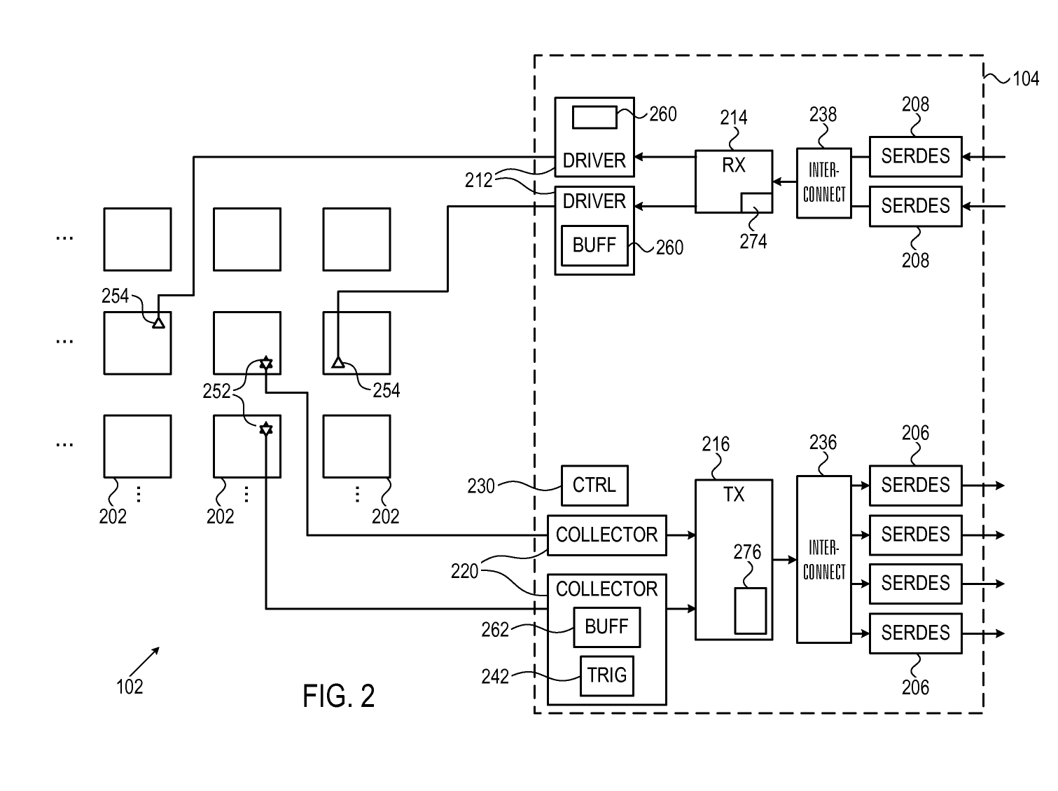

FIG. 2 is a schematic illustration of target FPGA 102 with an emphasis on embedded agent 104, in accordance with an embodiment of the invention. Target FPGA 102 includes a plurality of cells 202 of gates, which are configured by the user to perform a desired task, as is known in the art. Embedded agent 104 is placed in target FPGA 102 in order to collect signals from desired collection points 252 in cells 202 and export them in real time to computer 110 (FIG. 1) for analysis, and optionally also to receive signals from computer 110 and place them in real time at desired drive points 254. The desired collection points 252 are optionally indicated by a human operator based on a desired analysis task. The collection points 252 are positioned on control and/or data lines of interest, depending on the specific analysis task that the operator wants to perform. The signals are optionally collected at an operation rate of target FPGA 102 or even at a higher rate, so as to allow complete construction of the internal signals of target FPGA 102. Optionally, the operation rate is at least 1 MHz, or even at least 500 MHz, such that at least 500 million clock cycles are performed each second. Alternatively, the signals may be collected at lower rates, in order to reduce the amount of data collected, but preferably at a relatively high rate, for example, at least once every five clock signals or even at least every three clock signals.

Generally, target FPGA 102 includes a large number of cells 202, more than a thousand, tens of thousands, hundreds of thousands or even more than a million, but for simplicity of FIG. 2 only a small number are shown. In addition, to aid in the present discussion, FIG. 2 has emphasis on the details of embedded agent 104, although agent 104 optionally covers only a small portion of the area of target FPGA 102, possibly less than 10%, less than 1% or even less than 0.1%.

### Communications

For reception and application of driving signals, embedded agent 104 optionally includes one or more high speed serializer/deserializer (Serdes) input transceivers 208, a protocol interconnect unit 238, a receiver 214 and one or more drivers 212. The communication units of embedded agent 104 are provided separately from any communication interfaces of target FPGA 102. Embedded agent 104 optionally operates independently of target FPGA 102 without interfering with its normal operations and/or with its communications with other units. The communication units of embedded agent 104, used to export signals from the chip are optionally performed without passing through a protocol stack and/or other communication units of target FPGA 102.

In the opposite direction, one or more collectors 220 collect signals from desired collection points 252, and pass them to a transmitter 216, which organizes them in packets. The packets are provided to one or more output protocol interconnect units 236 which transmit them through one or more transceivers 206 to communication unit 108. These elements of agent 104 implement a protocol stack for transmission and reception of signals.

Transceivers 206 and 208 perform tasks of a physical signaling layer. The signaling layer is governed by a suitable protocol, such as low-voltage differential signaling (LDVS) or Gigabit transceiver (GX), although other protocols may be used. In some embodiments of the invention, all of transceivers 206 and 208 operate according to the same protocol. Alternatively, different transceivers operate according to different protocols. Each transceiver 206, 208 optionally corresponds to a single pin of the chip of integrated circuit 102, allocated to agent 104. Transceivers 206, 208 optionally operate at rates of between about 1-10 Gbits per second, although higher or lower rates may also be used. The number of transceivers 206 and 208 included in embedded agent 104 is optionally selected at the time of configuration of target FPGA 102, according to the required communication bandwidth between embedded agent 104 and communication unit 108. In some embodiments, the required bandwidth is estimated based on the number of drive and collection points and their clock rates.

It is noted that transceivers 206 and 208 may be physically designed for one way transmission or reception, in which case they may be referred to as transmitters or receivers, or may be two way transmission transceivers, used for transmission in only a single direction or in both directions.

Interconnect units 236, 238 manage the transmissions through transceivers 206, 208, respectively, according to a physical interconnect layer, such as Interlaken or SPI-4.2. In some embodiments, a single interconnect unit 238 handles all of transceivers 208, such that receiver 214 receives packets from a single entity. Alternatively, agent 104 may include a plurality of interconnect units 238, possibly a single unit 238 for each transceiver 208, for example when different transceivers operate in accordance with different protocols. Similarly, one interconnect unit 236 may be used for all of transceivers 206 or several interconnect units 236 may be used.

Above the interconnect layer, the protocol stack includes a packet switch and/or router, implemented by receiver 214 and transmitter 216. Receiver 214 directs received packets to their intended driver 212 and transmitter 216 collects packets from the various collectors 220. Receiver 214 optionally parses the headers of the received packets to determine their destination. The signals in correctly received data packets are optionally transferred to one of drivers 212, identified by a destination field in their header. The receiving driver 212, applies the received signals to a corresponding drive point 254. Correctly received control packets are transferred to a controller 230. In embodiments in which more than a single reception interconnect unit 238 is used, receiver 214 aggregates the packets from the different interconnect units 238. Similarly, when a plurality of transmission interconnect units 236 are used, transmitter 216 manages the distribution of the packets between the interconnect units 236.

In some embodiments of the invention, receiver 214 is configured to verify that the received packets of each buffer 260 have consecutive packet numbers in their header and to request retransmission of data packets not received. Optionally, receiver 214 includes a packet buffer 274 in which packets are stored while waiting for retransmission of preceding packets. Alternatively or additionally, the data of later packets received before earlier packets not yet received is stored within the buffer 260 in a manner leaving a gap for the forthcoming missing data. The retransmission requests are optionally given priority over all other packets to ensure the retransmitted data is received on time. Alternatively or additionally to requesting retransmission, receiver 214 is configured to correct errors. Optionally, each packet may include redundant information which may be used for error correction, for example in accordance with Reed-Solomon or CRC.

Optionally, different error correction/detection schemes are used for transmitting to agent 104 and from agent 104. In transmitting from agent 104, an error detection/correction code which is relatively simple to calculate is used, with a relatively complex error detection/correction method at the receiver, as the error correction/detection is performed by communication unit 108 and/or computer 110. On the other hand, for packets transmitted to agent 104, a relatively complex error detection/correction code, which allows checking for errors and/or correcting them with minimal resources, is used. Alternatively, the same error correction/detection method is used in both directions.

In some embodiments, a CRC code is added to the transmitted packets and if there is an error, the receiver determines which bit if changed would result in a correct code. Optionally, an algorithm based on the linear nature of the CRC code, having linear complexity, is used to determine the erroneous bit location.

Transmitter 216 is optionally configured to store packets it transmits in a transmission buffer 276 for a short period, for example until an acknowledgement of reception is received or until a predetermined time has passed. Embedded agent 104 is optionally configured to receive retransmission requests from communication unit 108 and respond with retransmission of the requested data. In other embodiments, retransmission is not performed, for example when the connection between agent 104 and communication unit 108 has a very low BER (Bit Error Rate) and/or when an error correction scheme is used.

As is known in the art, different points 252 and 254 may operate at different rates. Buffers 260 and 262 serve to bridge between the particular clock rates of the drive and collection points 252 and 254 on one side and transmitter and receiver 214 and 216 on the other side.

### Collector

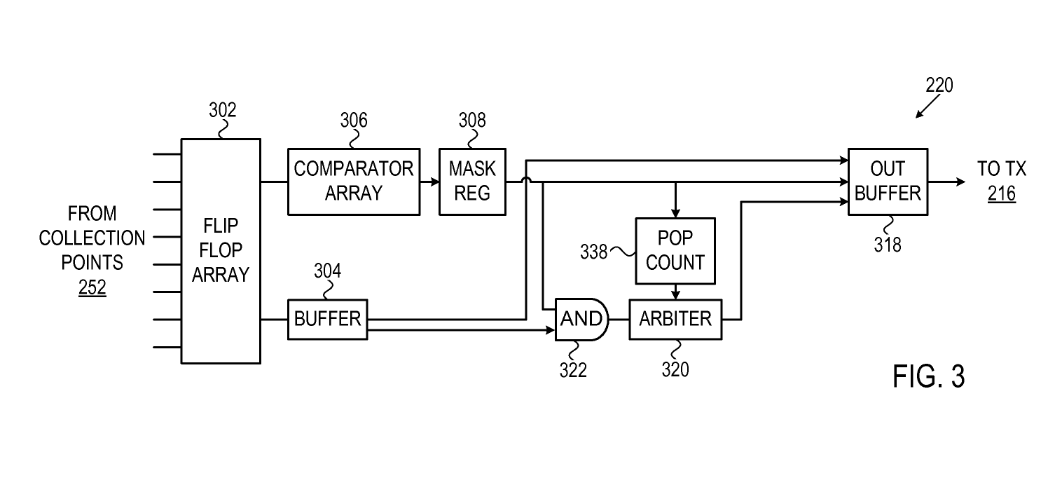

FIG. 3 is a schematic block diagram of a collector 220 which compresses the collected signals, in accordance with an embodiment of the invention. Collector 220 comprises a flip flop array 302 which receives a plurality (L) of signals from respective collection points 252. In each clock cycle, flip flop array 302 collects L signals from the respective collection points and passes the previous L clock signals to a buffer 304 which collects signals of a predetermined number (REP_NUM) of cycles for compression together. The L signals of each cycle are referred to herein as a word and the words in buffer 304 handled together are referred to herein as a block of words. In parallel, the previous cycle signals are optionally provided to a comparator array 306, which includes another array of L flip flops and an array of L comparators. In each clock cycle, the comparator determines which of the L signals changed between the previous cycle and the current cycle, such that over a block of REP_NUM cycles, the comparators determine which of the L signals of the current word remained constant over the entire block. Optionally, the determination is performed by comparing the values for each two consecutive cycles and setting to ‘1’ the output for lines which changed. The result is optionally stored in a mask register 308, which after REP_NUM cycles indicates with ‘1’, those signals that changed during the REP_NUM cycles and with ‘0’, those signals from the L flip flops, that did not change over the REP_NUM cycles. A word formed of the L signals for one of the REP_NUM cycles, for example, the first cycle, together with the mask are provided to an output buffer 318, from which they are passed to transmitter 216 for being exported out of target FPGA 102 to computer 110. The exported word, referred to herein as a block-representative word, and corresponding mask indicate to computer 110 the values of those bits which did not change over the REP_NUM cycles.

The values in the buffer, after a delay of REP_NUM cycles from reception of the first word, are transferred to a signal canceller, for example an AND gate 322, which sets the values of the lines that did not change to a predetermined constant value, for example ‘0’. Optionally, AND gate 322 receives the delayed values in the buffer with the corresponding mask from mask register 308, such that bits that do not change are set to ‘0’ in the output of the AND gates 322. The output of AND gate 322 may be represented by the equation: yᵢ=xᵢ AND mᵢ, in which m is the mask, x is the data entering collector 220 from collection points 252, y is the output of AND gate 322, and i represents the indices of all the positions in the data word being handled, i=1 . . . L.

The resulting values yᵢ are provided to an arbiter 320 which prepares a compressed output which represents the bits of the words that changed. A pop counter 338 optionally adds up the bits of the corresponding mask of the block to determine the number P of bits that changed during the REP_NUM cycles, and provides the number P to arbiter 320, which accordingly determines the number of bits to be used to represent the changing data. The representing bits provided by arbiter 320 are passed to output buffer 318 for export along with the mask and the representative word of the current block. Together, these are used by computer 110 to reconstruct the original data of the block.

In some embodiments of the invention, arbiter 320 comprises an array of multiplexers, which are used to select the bits that changed from the other bits which were zeroed by AND gate 322. While these embodiments are relatively simple, the area required by the multiplexers of arbiter 320 is relatively large.

In other embodiments, arbiter 320 generates a plurality of equation bits, each of which is a linear combination (e.g., XOR combination) of a different arbitrary sub-group of bits from the L bits of the word (zᵢ=XOR_sub_group (yᵢ . . . y_{L})). Arbiter 320 outputs a number of equation bits required to represent the bits that changed in the current word.

Each sub-group optionally includes about half the bits of the output of AND gate 322, e.g., L/2. In some embodiments of the invention, all the sub-groups of the equations include the same number of bits. Alternatively, different equations depend on sub-groups of different numbers of bits of the output of AND gate 322, as such diversity was found to increase, in some cases, the independence of the equations. Optionally, some of the equations depend on a sub-group including an even number of bits of the output of AND gate 322, while others depend on a sub-group including an odd number of the bits.

Optionally, arbiter 320 generates for each clock cycle a maximal number of equation bits and only a sub-group of a required number of equation bits is output to the transmitter 216 (FIG. 2). The number of equation bits that is output, is optionally selected responsively to the number P of changing bits in the current block of words, such that the chances that the original data will not be reconstructable by computer 110 is below a desired threshold (e.g., 1 in a billion or 1 in a trillion). In some embodiments, the number of equation bits transmitted is equal to the number of changing bits P. Alternatively, the number of transmitted equation bits is equal to the number of changing bits P multiplied by a safety factor, such as 1.1 or 1.2. Further alternatively, the number of transmitted equation bits is equal to the number of changing bits P in addition to a predetermined number (e.g., between 2-6) of extra bits for redundancy.

Optionally, in generating the equations, the same respective sub-groups of bit locations for each specific equation, are used in all the cycles. Alternatively, for one or more of the specific equations, different sub-groups are used in different clock cycles, for diversity. In some embodiments, the same sub-groups are used in generating the equation bits, but in the transfer of the equation bits to be output, a selection process is used so that in different clock cycles different ones of the generated equation bits are output.

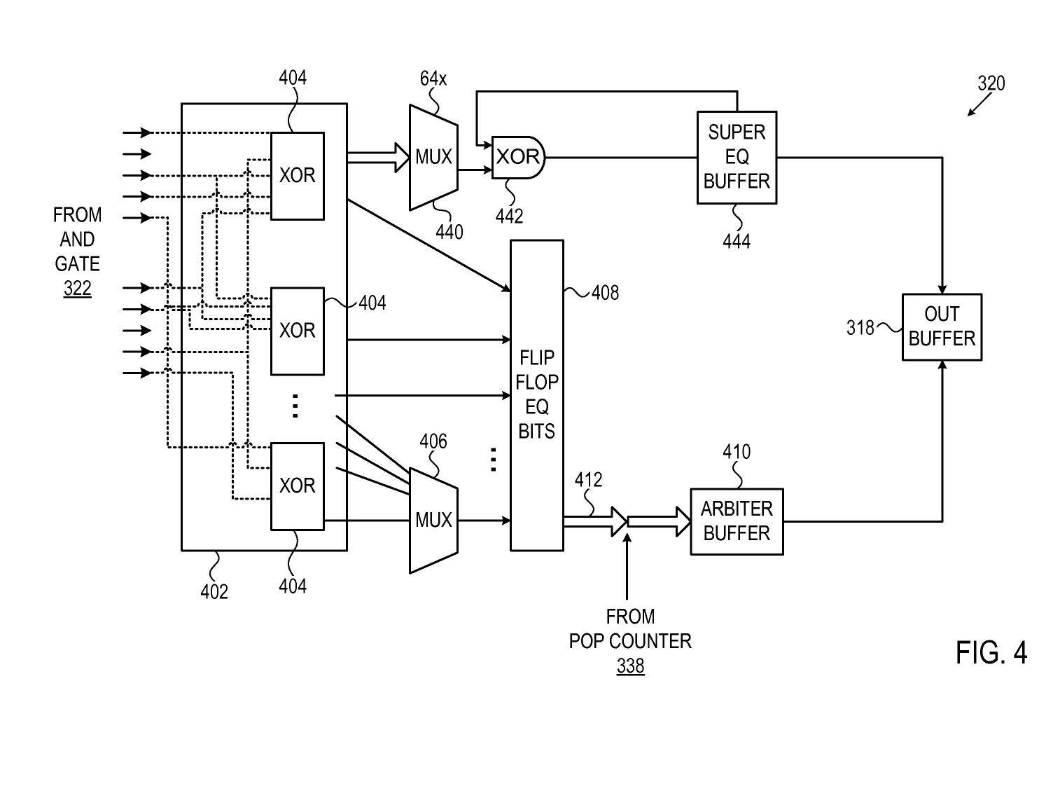

FIG. 4 is a schematic block diagram of arbiter 320, in accordance with an embodiment of the invention. In the embodiment of FIG. 4, arbiter 320 comprises an equation array unit 402 (also referred to herein as a linear combination calculation circuit), which includes a plurality of XOR gates 404 which each receives a different sub-group of the input bits received by arbiter 320 from AND gate 322. In some embodiments, in order to vary the equations used for different cycles, equation array unit 402 includes a number of XOR gates 404 larger than the maximal number of bits which may be required for transmission (e.g., when all of the bits in a word block change within the block). One or more multiplexers 406, which optionally vary their selection based on a clock signal of arbiter 320, select different XOR gate outputs for different clock cycles. The selected bits are passed to a flip flop array 408 of equation bits. Optionally, some of the XOR gate outputs are passed in all cycles, without multiplexer selection, to flip flop array 408. Alternatively, all the equation bits transferred to flip flop array 408 are transferred by respective multiplexers 406.

A bus 412 transfers to an arbiter buffer 410 a number of equation bits selected responsively to the output of pop counter 338. In some embodiments of the invention, the equation bits in flip-flop array 408 have a priority order and the N bits transferred to arbiter buffer 410 are always the first N bits in the priority. Optionally, at least some of the equation bits that are transferred less often due to their low priority are passed from equation array unit 402 to flip flop array 408 without passing through a multiplexer 406. In other embodiments, the bit locations in flip flop array 408 transferred by bus 412 to arbiter buffer 410 are changed cyclically. Optionally, the bits that are transferred on bus 412 are determined as those corresponding to the current locations of arbiter buffer 410 that need to be filled.

In one example embodiment, each word includes L bits and equation array unit 402 includes L+X1 XOR gates 404, where X1 is a predetermined number which allows for selection of different XOR gate outputs, as discussed above. Optionally, X1 is greater than 15, greater than 30 or even greater than 60, e.g., X1=64. Flip flop array 408 optionally includes L bits, which is the maximal number of bits to be used, e.g., when all the bits of the word in a specific block changed during the block. Since arbiter buffer 410 collects data of a varying amount depending on the amount of bits that changed in the current word block, arbiter buffer 410 optionally includes room for a word of a size suitable for export to out buffer 318 and from there to transmitter 216, in addition to sufficient room for storing additional data being received until the accumulated data is transferred to out buffer 318. In some embodiments, arbiter buffer 410 includes two words of the size of the export to out buffer 318. Optionally, the size of the word exported to out buffer 318 is L, which is the same size as the mask and block-representative word received by out buffer 318. In some embodiments, L is 64, 128 or 256, although larger, smaller or intermediate values may be used.

Each multiplexer 406 is optionally connected to 4 or 8 XOR gates 404, although larger or smaller multiplexers may be used. In some embodiments, all the multiplexers 406 have the same size. In other embodiments, different multiplexers have different sizes. Optionally, some or all of the paths from XOR gates 404 to flip flop array 408 do not include multiplexers at all. Optionally, in cases in which the outputs of XOR gates 404 have different probabilities of being transferred to out buffer 318 for being exported, larger multiplexers are optionally used for the signal lines with higher probabilities of being exported, and smaller multiplexers and/or no multiplexers are used on lines carrying signals with low chances of being exported.

In some embodiments, arbiter 320 also includes an array of multiplexers 440 which select bits for generation of super equations. Each multiplexer 440 is connected to an arbitrary set of XOR gates 404, and in each clock cycle selects the output of one of the XOR gates 404, for example based on the current clock bits. The selected bit of each multiplexer 440 is provided to a respective XOR gate 442, which performs a XOR operation with a previous buffered value of the multiplexer, stored in a super-equation buffer 444. The XOR over time cycles is optionally performed for a predetermined number of cycles, e.g., 16 or 32, and then the results are passed to out buffer 318 and super-equation buffer 444 is initialized, e.g., to ‘0’ bit values. Thus, additional diversity is added to the compression, increasing the chances of successful decompression by computer 110. The number of XOR gates 442 is optionally 64, so that if a super-equation batch includes 16 cycles, the addition for the 64 bits of super equations is 4 bits per clock cycle. If a super-equation batch includes 32 cycles, the addition is 2 bits per cycle. It is noted that other numbers of XOR gates 442 may be used.

The same compression method is optionally used in all of collectors 220. Alternatively, different compression methods are used for different collectors 220 according to attributes of the expected data passing through the collector. For example, different collectors 220 may use different block sizes and/or different super-equation batch sizes. Larger sizes are optionally used for data with lower change rates.

It is noted that a structure similar to that of arbiter 320 may be used for other on-chip selection tasks which require selection of K lines out of N lines for signal export, instead of using a large array of multiplexors. For example, target FPGA 102 may include a larger number of collection points 252 than collectors 220 and the selection of the collection points 252 connected to the collectors may be performed using an intermediary arbiter 320, which has much lower on-chip area requirements than multiplexers. The lines that are not currently selected are optionally set to zero by an array of AND gates.

### Computer

Computer 110 manages for each collector 220 which performs compression, a respective de-compressor configured with the exact functions of each of the bits received and which reconstructs the original signals from the received compressed bits. For example, for each word block, the received mask and block-representative word are analyzed to determine the bits that did not change over the words of the block. The mask is also used to determine the number of bits that changed and accordingly, the words representing the changing bits are parsed. The parsed signals are used to reconstruct the original bits using methods known in the art.

Computer 110 may optionally use the signals output by embedded agent 104 from target FPGA 102 for various tasks, including analysis, testing, optimization, monitoring and/or debugging.

The collected signals transmitted to computer 110 may be analyzed using any method known in the art. For example, the collected signals may be graphically displayed on a waveform viewer and/or on a HEX editor for manual inspection and analysis by user. Alternatively or additionally, the collected signals may be provided to an RTL (Register-transfer level) or ESL (Electronic system level) Testbench environment designed to simulate part of all of the integrated circuit in the target device. The Testbench may be used to automatically check validity and/or correctness of the collected signals and/or to generate the drive signals provided to drive points. In some embodiments of the invention, the signals are displayed on a software based dashboard platform.

Computer 110 is optionally used to specify drive signals to be generated. Optionally, the user may indicate the desired signals in various levels and computer 110 converts the user request into the actual drive signals. For example, the user may provide data which is to be transmitted in the form of UDP packets at a specific drive point and computer 110 generates packets for the data and drives the point with the bits of the generated packets.

In some embodiments, computer 110 passes the signals of one or more collection points to a modeling program, such as Matlab or Simulink. The modeling program may be used to filter the signal, or to perform analysis in time and/or frequency domain. This analysis is particularly useful when the signals of a collection point represent a physical quantity, such as samples of an analog-to-digital converter (ADC), where the analog signal corresponds to a voltage level representing an electromagnetic signal.

The modeling program may also be used to generate signals of a desired characteristic for driving one or more drive points. For example, the modeling program may generate a digitally sampled analog signal which corresponds to a simulative electromagnetic signal, which is meant to drive a digital output which drives a digital-to-analog converter (DAC).

In some embodiments, the analysis of the signals includes reconstructing higher level structures, such as communication packets, from the signals. For example, if the signals at a specific collection point are supposed to represent packets according to a specific protocol, such as TCP, UDP and/or IP, computer 110 optionally runs a software packet analyzer which the packets passing at the point, from the signals and optionally indicates errors and/or unexpected values in the reconstructed packets. The packet analyzer is optionally used to view the contents of the packets in any desired protocol layer, including the payload. In some embodiments, when data is collected from a plurality of different points representing communication packets or other data structures, the packet analyzer on computer 110 may compare the packets at the different points. The travel of the packets between different points may be presented to the user graphically on a map of the points or in any other method.

Optionally, the collected signals retrieved for analysis by agent 104 are displayed by computer 110 along with corresponding signals provided by target FPGA 102 through its regular operational interface. Thus, the meaning of the analysis signals can be more easily correlated with the operation of the target FPGA 102.

The payload of the data is optionally also displayed, optionally along side with the raw data. For example, when the payload includes audio, video or text data, for example, the data is optionally displayed on one side as video, audio or text, and on the other as raw data, allowing an operator to easily determine the content of the data.

In some embodiments of the invention, the display groups together data from different internal lines, which are related. For example, control, address and/or payload signals of a bus are optionally displayed together, along with explanations of their content. Particularly, for control signals, computer 110 optionally displays them along with their meaning.

Optionally, computer 110 is configured based on the signals passing on one or more lines to reconstruct the contents of internal units of target FPGA 102 which are not directly exported. For example, based on signals passing on a bus connected to a memory, stack, counter, register or other internal structure, computer 110 optionally determines and displays the contents of the memory or other structure.

### Input-Based Testing

In some cases, target FPGA 102 is tested for a specific input of data provided by computer 110. If output from a relatively large number of points is desired, the volume of the output may be larger than can be outputted by embedded agent 104. Optionally, in such cases, the input is provided to the target FPGA 102 a plurality of operation rounds and in each operation round a different portion of the output is exported to computer 110. Computer 110 optionally aggregates the exported output and provides the output to the operator together as if it was all outputted from a single test.

Optionally, for one or more of collectors 220 (FIG. 2), a plurality of lines from sampling points providing a bandwidth greater than can be handled by the collector, are connected to the collector through a multiplexer. In each of a plurality of test rounds for the same input, the multiplexer is set to provide to the collector a different one of the sampling lines.

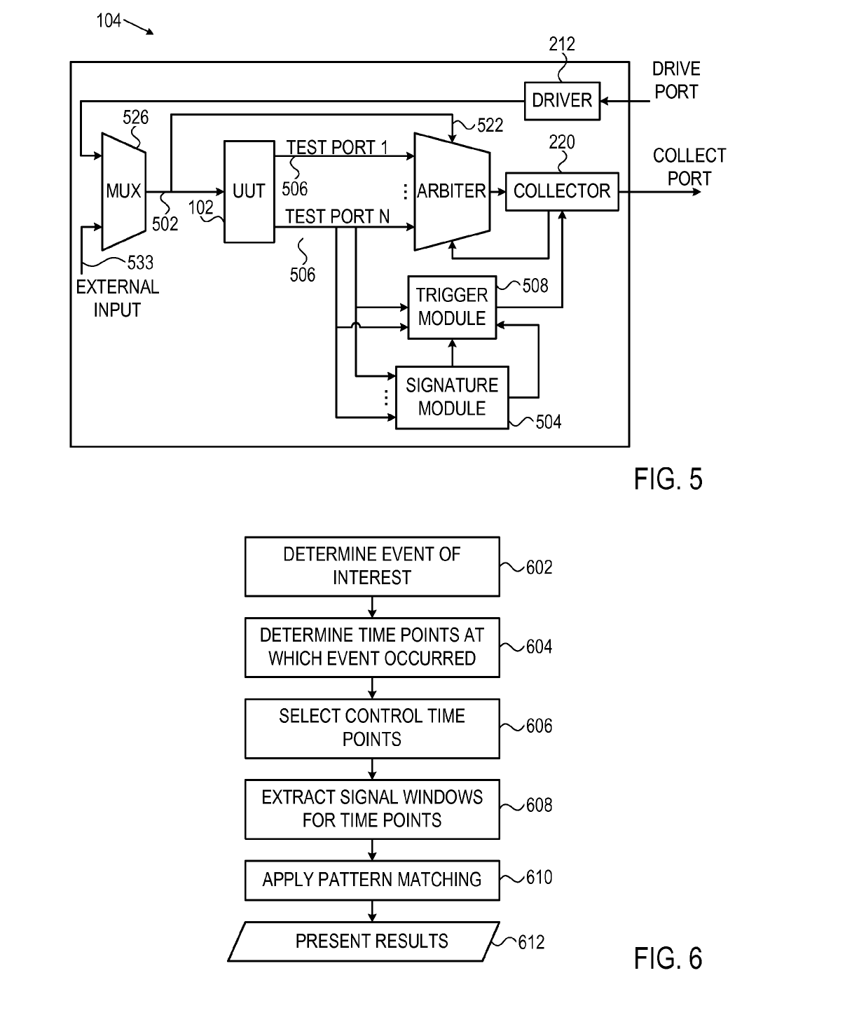

FIG. 5 is a schematic block diagram of an arrangement for repeated testing of a target FPGA 102, in accordance with an embodiment of the invention. The signals from target FPGA 102 to be output by collector 220 are passed on output lines 506 of target FPGA 102 through an arbiter 510, which in different operation rounds of a specific test performed by target FPGA 102, provides data from a different line 506. A plurality of operation rounds are performed for the same external input provided on an input port 502 of the target FPGA 102, where in each round signals from a different one lines 506 is passed by arbiter 510 to collector 220.

In some embodiments of the invention, in order to verify that the plurality of operation rounds are identical in their output and/or in order to properly synchronize the output of the different rounds, a signature module 504 is provided in embedded agent 104. Signature module 504 receives the output from some or all of the output lines 506 and generates signatures which are stored and used to compare the signals passing on output lines 506 from different operation rounds. A triggering module 508 optionally controls the operation of collector 220. In some embodiments, triggering module 508 receives from signature module 504 indications of whether the signatures of different operation rounds properly match and if non-matching signatures are identified, a warning is optionally exported with the exported signals or instead of the exported signals. In other embodiments, the signature comparison results are exported without being passed to triggering module 508.

In one embodiment, during a first operation round of a multi-round test, signature module 504 calculates and stores signatures for the signals on all the output lines 506. In subsequent operation rounds, the signature of the data of the output line 506 currently being output is calculated and compared to the corresponding stored signature, to verify that the data did not change. It is noted that the first round may include exporting data of a first output line 506 or may be dedicated to signature calculation without data export, or with export of the external input, as discussed in detail hereinbelow.

Alternatively, in each operation round, signature module 504 calculates for storage a signature for a single one of the output lines 506, for example, for the currently exported output line 506, or for a limited number of lines (e.g., up to 5 lines). In each operation round, signature module 504 calculates signatures for some or all of the output lines 506 for which stored signatures are available and compares the currently calculated and previously stored signatures for verification.

The signatures include, for example, parity bits, a cyclically redundancy check (CRC), a checksum, a cryptographic hash function or any other function of the signals, suitable for error detection. In some embodiments of the invention, the signature is a function of the signals in the entire duration of each operation round. Alternatively, the signature is a function of the signals in a sub-period of the operation round, for example, a beginning or ending period. Further alternatively, for each output line 506, a plurality of signatures are calculated for different sub-periods of the operation rounds. The sub-periods may be overlapping or non-overlapping.

In some embodiments of the invention, for cases in which the external input of target FPGA 102 is not easily reproducible by the user for the plurality of operation rounds, embedded agent 104 optionally includes a setting for recording the external input in the first round and then reproducing it in the remaining rounds. For short external inputs, the external input may be stored within embedded agent 104 on the chip. Longer external inputs may be too long to store on the chip. Optionally, a bypass line 522 passes the external input to arbiter 510, which in a first operation round passes the external output to collector 220, instead of, or in addition to, the data from one of the output lines 506. Collector 220 outputs the data from bypass line 522 to computer 110 or some other external unit, where it is stored for use in the subsequent operation rounds of the current test. In the subsequent operation rounds, the stored data from the external input is provided to a driver 212 and from there is passed over a line 524 to a multiplexer 526, which provides the stored external input from the previous operation round, instead of the data on the external line 533, to the input port 502 of target FPGA. Thus, there is no read for a human operator to manage storing an accurate identical copy of the external input, as the storage is managed by embedded agent 104.

### Statistical Analysis

FIG. 6 is a flowchart of acts performed by computer 110 in analyzing the signals, in accordance with an embodiment of the invention. Computer 110 determines (602) an event of interest which is to be analyzed. Computer 110 then reviews the signals retrieved from a first group of one or more lines from which the occurrence of the event can be determined, to determine (604) time points at which the event occurred. In addition, computer 110 optionally selects (606) a plurality of time points, referred to herein as control time points, at which the event did not occur. For each of the selected time points, a window of signals immediately preceding the time points are extracted (608) from a second group of one or more lines and a pattern matching algorithm is applied (610) to the extracted windows of signals, to determine lines for which a significant difference can be identified between the signal windows before occurrences of the event and the signal windows before time points at which the event did not occur. The determined significant differences are optionally presented (612) to the user, who can decide whether the difference is indicative of a cause of the event.

Referring in detail to determining (602) an event of interest, in some embodiments of the invention, the event is determined by a human user who selects a desired event from a list of events with which computer 110 is configured or indicates an event and the line and value that indicate occurrence of the event. Alternatively or additionally, computer 110 may sequentially perform the method of FIG. 5 on a plurality of events from a list of events and/or may randomly select an event from the list. Further alternatively or additionally, computer 110 reviews the signals retrieved from target FPGA 102 to determine signals that usually have a standard value and change relatively rarely to a different value, and suggests these determined signals to a human operator as possible events.

The analyzed data may include, for example, signals of a data bus, such as control lines of the bus (e.g., sink busy line, data valid strobe) and the data lines of the bus. For memory mapped buses, the monitored signals may include the address lines, the data lines and/or the control signals (e.g., slave busy line). Other lines of particular interest include interrupt request signals. It is noted that the signals exported from target FPGA 102 may include any other signals internal to the target FPGA 102, as the export of the signals is performed substantially without interfering with the normal operation of target FPGA 102.

The determined events may include, for example, occurrence of a sink busy state of a data bus when a different unit is set to transmit data onto the bus. Other events may include cache miss, occurrence of interrupts, such as a software failure interrupt, overflows (e.g., buffer or FIFO overflows), and/or unexpected states of a line, when a line has a value which is not suppose to occur (e.g., a control line, which has values not used) or values which are indicative of errors. In some embodiments, one or more events are defined as combinations of specific respective values on a plurality of different lines that should not occur together. The Events may also be ones which occur more regularly, such as appearance of a packet start signal or packet end signal on a bus and/or any other specific data or control signal of interest.

Other events relate to an extent or pattern of the utilization of a bus or other line. For example, an event may be defined as a time point after a period in which the utilization of a bus is above or below a given threshold or in which the utilization rate changes abruptly.

As to selecting (606) the time points at which the event did not occur, the same control time points are optionally selected for all the lines of interest from which data is received. Alternatively, different control time points are selected for each line separately. The control time points are optionally selected randomly, while randomly selected time points which are closer than a predetermined number of clock cycles (e.g., at least 100 cycles, at least 500 cycles) to an identified event, are excluded. In some embodiments, the control time points are selected at predetermined evenly spaced intervals, except that intervals found to be too close to an identified event are excluded or replaced by another non-event time point at a close time point.

As to extracting (608) a window of signals from a second group of one or more lines, in some embodiments, the window is of a predetermined size, for example a size between 128-1024 clock cycles, although larger (e.g., between 1024-4092 cycles) or smaller (e.g., 32-128 cycles) sizes may be used when suitable. Alternatively, for each line, a window size is defined depending on the type of data passing on the line. For example, control signals may use a smaller or larger window than data signals. The size of the window depends in some embodiments, on the type of analysis performed on the signals, as discussed hereinbelow.

The second group of lines includes, in some embodiments, the first lines from which the event is determined. In other embodiments, the second group of lines does not include the first lines.

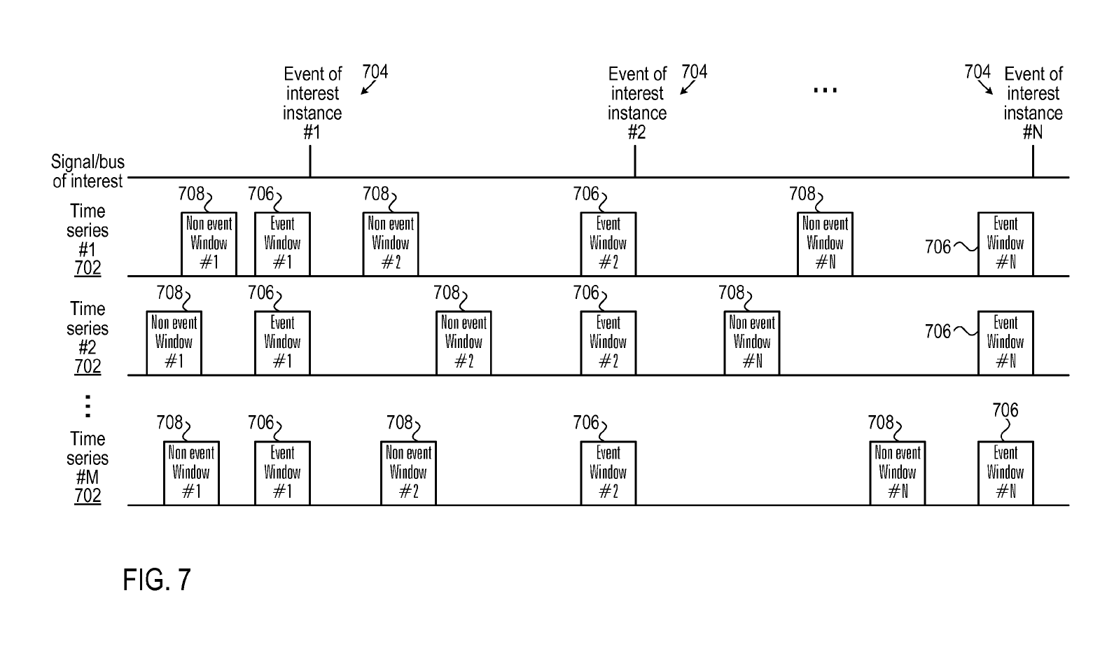

FIG. 7 is a schematic illustration of a plurality of lines monitored for on-chip statistical analysis, in accordance with an embodiment of the invention. Computer 110 receives the signals of a plurality of lines 702. For each time point 704 of an event, a signal window 706 is collected for the event, immediately before the time point, for each of lines 702. Non-event windows 708 of the same length as event windows 706 are located at points remote from the event time points 704.

As to applying (610) the pattern matching algorithm, in some embodiments, a pattern matching is performed on the signals themselves. Various pattern matching algorithms may be used depending on the type of data passing through the analyzed signals. An example of a pattern matching algorithm applicable in case of state machines or control fields, is to identify specific state values which appear at a high rate on one or more lines in the event windows but appear in a low rate or do not appear at all in the non-event windows.

In some embodiments, rather than directly performing the pattern matching on the signals themselves, one or more descriptors are generated for each of the windows and the correlation is performed on the descriptors. The descriptors include, for example, transmission throughput of a bus, stream data bus packet length, a length of a space between packets on a data bus, a data bus sink maximal throughput, memory mapped bus transaction size, memory mapped bus data write throughput, memory mapped bus data read throughput, memory mapped bus read latency, and/or any other descriptors based on the structure of the data. In some embodiments, the descriptors may include the number of occurrences of specific signal profiles in each window. For example, a descriptor may be set to the number of times the signals change values within the window.

In some embodiments of the invention, the descriptor is calculated for a plurality of time points in each window, possibly for each clock cycle, or for each 5 or 10 clock cycles. The generation of the descriptors optionally results for each window in a time series of values of the descriptor forming a vector of one-dimensional time-functions. The behavior of the vector indicates a profile of the sampled signal or bus. Optionally, an analysis determines high or low values of the vector and/or high or low rate of change of values in the vector. These high or low values are used to analyze the signal or bus, or even an entire system or subsystem in the circuit being analyzed.

In some embodiments, a high pass filter over time is applied to local windows of the vector for each descriptor in order to find singularities. Optionally, a maximum point of the absolute value of the filter output is identified and a pattern around the maximum point is optionally extracted. The patterns extracted from the event windows and the control windows are compared to determine a level of correlation of the patterns of the event windows and a level of correlation of the control windows. Optionally, if the difference between the correlations of the patterns of the event windows and of the control windows is greater than a predetermined threshold, the pattern is marked as a possible cause of the event. The threshold is optionally set to a value of a fixed margin above the maximal correlation between search patterns and reference threshold over the non-event windows.

The analysis may be performed for each descriptor line separately (set of one-dimensional filters) or may be performed for a plurality of descriptor lines together (high dimensional filter) in order to find more complex relations between the signals.

In presenting (612) the determined significant differences, computer 110 optionally presents to the user the signals at the time points which are suspected as related to the event.

In analyzing signals collected from one or more memory mapped busses (e.g. AMBA AXI), the collected signals are optionally transformed into a transaction representation, by identifying signal sequences which together form a bus transaction. A bus transaction may include, for example, the fields: transaction timetag, read/write indication, length, Bus-master ID number, address, latency. The fields of the bus transaction are optionally configured into the analysis tool on computer 110, according to the type of the bus being analyzed. Optionally, the analysis tool is configured with field structures of a plurality of different types of buses. The user optionally indicates for each collection point, the type of the bus. Alternatively or additionally, the analysis tool automatically determines the type of the bus, for example by attempting to match the signals passing on the bus with a plurality of different signal structures and selecting a best match.

Optionally, after combining the signals of the bus into transactions, the transactions may be used for statistical analysis of the bus operation. The statistical analysis optionally includes determining for each transaction one or more parameters, such as latency, accessed bank address, accessed row, length and read/write. The user optionally requests information on the general distribution of one or more parameters and/or the dependence of one or more parameters on one or more other parameters. The information may be provided to the user in various methods including text, table and graph formats. In some embodiments of the invention, the average throughput, busy state and/or latency of the bus for a given period length are determined for various time periods or in general. Alternatively or additionally, the statistical correlation or covariance between the throughput or latency of any two of the clients of the bus is calculated and presented to the user in text, table and/or graph formats.

### Delay

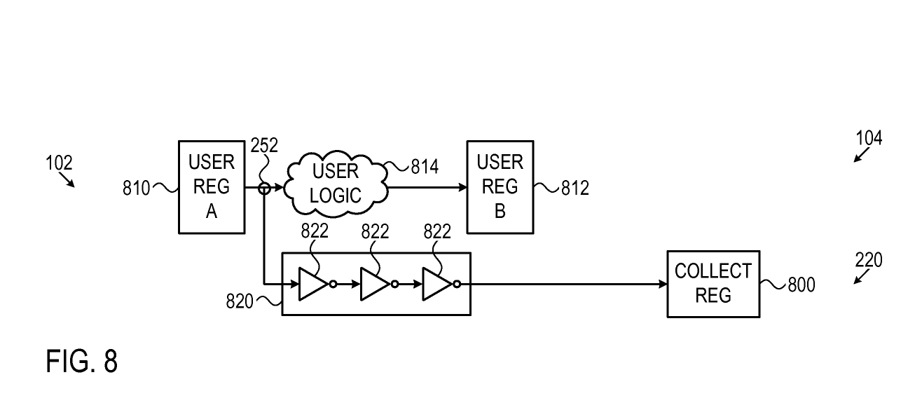

FIG. 8 is a schematic illustration of a connection between a collection point 252 and a collect register 800 of a collector 220 in embedded agent 104, in accordance with an embodiment of the invention. In order to allow for fast operation of the user circuit being tested, e.g., target FPGA 102, it is desired to minimize the distance between the user registers, such as user register 810 and user register 812, through logic elements 814, so that a fast clock may be used. Therefore, it is desired not to include collection registers for embedded agent 104 within the user circuit near registers 810 and 812. In cases in which a collection point 252 is far from its corresponding collect register 800 in embedded agent 104, the collected signals may not reach collect register 800 within a single clock cycle and therefore may not be sampled correctly.

In some embodiments of the invention, collection point 252 is connected to collect register 800 through an asynchronous shift register 820, for example formed of a cascade of not gates or other delay buffers. The number of delay buffers 822 included in the cascade is selected according to the chip process parameters and the length of the path from collection point 252 to collect register 800, so that the delay is definitely between M and M+1 clock cycles, for an arbitrary M. It is noted that different values of M may be used for different collection points 252. After signal export to computer 110, the computer adjusts the timing of the signals of the different collection points 252 according to their respective M, such that the signals are all compared on a single timeline.

### CONCLUSION

The methods of the above described embodiments may be used in various stages of integrated circuit development and utilization, including design stages before commercial production, testing (e.g., for quality assurance) after commercial production and field testing and troubleshooting after the integrated circuit is supplied to a customer. The small size of embedded agent 104 allows for including the agent in the integrated circuit provided to the end customer.

The term real-time transmission refers herein to transmissions performed within a short time from when the data was generated, such as within less than a minute or less than a second from the time the data was generated. In some embodiments of the invention, the data is transmitted to or from embedded agent 104 within less than 100 clock cycles or even less than 50 clock cycles between its transmission and when the data was generated and/or when the data is applied to a drive point.

The term operation rate of a signal refers herein to a rate at least of the order of the normal operation rate of the signal.

It will be appreciated that the above described methods and apparatus are to be interpreted as including apparatus for carrying out the methods and methods of using the apparatus. It should be understood that features and/or steps described with respect to one embodiment may sometimes be used with other embodiments and that not all embodiments of the invention have all of the features and/or steps shown in a particular figure or described with respect to one of the specific embodiments. Tasks are not necessarily performed in the exact order described.

It is noted that some of the above described embodiments may include structure, acts or details of structures and acts that may not be essential to the invention and which are described as examples. Structure and acts described herein are replaceable by equivalents which perform the same function, even if the structure or acts are different, as known in the art. The embodiments described above are cited by way of example, and the present invention is not limited to what has been particularly shown and described hereinabove. Rather, the scope of the present invention includes both combinations and subcombinations of the various features described hereinabove, as well as variations and modifications thereof which would occur to persons skilled in the art upon reading the foregoing description and which are not disclosed in the prior art. Therefore, the scope of the invention is limited only by the elements and limitations as used in the claims, wherein the terms “comprise,” “include,” “have” and their conjugates, shall mean, when used in the claims, “including but not necessarily limited to.”

1. An integrated circuit, comprising:
a target circuit on a chip; and
an embedded agent on the chip, including:
a signal collector configured to collect from the target circuit signals of a plurality of single bit lines;
a signal canceller configured to receive an indication of lines that are not to be exported, for a given time period, and to set the indicated lines to a constant value, for the given time period;
a linear combination calculation circuit configured to generate a plurality of different linear combinations of the values of the single bit lines, for the clock cycles of the given time period; and
a transmitter configured to export from the chip a sub-group of the linear combinations calculated by the linear combination calculation circuit for the clock cycles of the given time period, the sub-group including a number of linear combinations selected responsively to the number of lines set to a constant value.

2. The integrated circuit of claim 1, wherein the signal canceller comprises an array of AND gates.

3. The integrated circuit of claim 1, wherein the signal collector comprises a register or latch.

4. The integrated circuit of claim 1, wherein the linear combination calculation circuit includes XOR gates which calculate the linear combinations.

5. The integrated circuit of claim 1, wherein the linear combination calculation circuit calculates at least one linear combination from signals of a plurality of clock cycles.

6. The integrated circuit of claim 5, wherein the transmitter is configured to export a predetermined number of linear combinations calculated from bits of a plurality of different clock cycles and a variable number of linear combinations that each depend on bits of a single clock cycle.

7. The integrated circuit of claim 1, wherein the linear combination calculation circuit calculates most of the linear combinations it calculates from signals of a single clock cycle.

8. The integrated circuit of claim 1, wherein the embedded agent comprises a circuit which determines whether the signals on the single bit lines changed and indicates the lines that did not change during the given time period for setting to a constant value.

9. The integrated circuit of claim 1, wherein the embedded agent receives indication of the signals to be set to a constant value from outside the chip.

10. The integrated circuit of claim 1, wherein the linear combination calculation circuit is configured to generate each of the different linear combinations from between 40% to 60% of the single bit lines.

11. The integrated circuit of claim 1, wherein a plurality of the single bit lines belong to a single multi-bit bus.

12. The integrated circuit of claim 1, wherein the embedded agent is further configured to generate and export a mask which indicates the lines that were set to a constant value, for the given time period.

13. A method of exporting a selected sub-group of signals from an integrated circuit, comprising:
collecting, by a signal exporting circuit on a chip, signals of a plurality of single bit lines;
receiving an indication of lines that are not to be exported, for a given time period, and setting the values of the lines during the given time period to a constant value, by the signal exporting circuit;
calculating a plurality of different linear combinations of the values of the single bit lines, for the clock cycles of the given time period; and
exporting from the chip a sub-group of the calculated linear combinations, the sub-group including a number of linear combinations selected responsively to the number of lines set to a constant value.

14. The method of claim 13, wherein collecting signals of the plurality of single bit lines comprises sampling signals from one or more internal lines of an integrated circuit, for debugging or testing.

15. The method of claim 13, further comprising generating and exporting a mask which indicates the lines that were set to a constant value, for the given time period.

16. The method of claim 15, comprising exporting the collected signals for one of the cycles of the given time period.

17. The method of claim 13, wherein at least one of the exported linear combinations is calculated from bits of a plurality of different clock cycles.

18. The method of claim 17, wherein the exported linear combinations comprise a predetermined number of linear combinations calculated from bits of a plurality of different clock cycles and a variable number of linear combinations that each depend on bits of a single clock cycle.

19. The method of claim 13, comprising receiving the exported calculated linear combinations by a computer and reconstructing the signals of the single bit lines from the exported calculated linear combinations by the computer.

20. The method of claim 13, comprising determining whether the signals on the single bit lines changed and indicating the lines that did not change as the lines that are not to be exported.

21. The method of claim 13, wherein the indication of the lines that are not to be exported is received from outside the chip.

22. A method of receiving data from a chip, comprising:
configuring a computer with the details of linear combinations generated by a signal exporting circuit on a chip;
receiving, at the computer, linear combinations generated by the chip from signals on a plurality of lines during a given time period, and a mask indicative of lines that were set to constant values during the time period; and
reconstructing by the computer of the signals on the lines that were not set to a constant value for the given time period, by reversing the linear combinations.

23. The method of claim 22, further comprising receiving by the computer the values on the lines in one of the clock cycles of the given time period and reconstructing the values on the lines that were set to a constant value as the value in the received one of the clock cycles, for the entire given time period.

24. A method of analyzing operation of an integrated circuit, comprising:
collecting signals from a plurality of internal lines of the integrated circuit;
determining, by a processor, a plurality of time points at which an event occurred, responsive to signals from one or more of the internal lines;
selecting a plurality of time points at which the event did not occur;
extracting, for time windows in the vicinity of the determined and selected time points, respective signal windows from one or more of the lines from which signals were collected; and
determining, by the processor, a statistically significant difference between signal windows corresponding to occurrence of the event and signal windows not corresponding to the event, for at least one of the lines.

25. The method of claim 24, wherein determining, by the processor, a plurality of time points at which an event occurred comprises determining time points at which interrupts occurred.

26. The method of claim 24, wherein determining the statistically significant difference comprises calculating a descriptor for each of the windows and determining a statistically significant difference in the value of the descriptor.

27. The method of claim 26, wherein the descriptor comprises a throughput or a signal latency.

28. The method of claim 26, wherein the descriptor comprises a packet length or a period between packets.

29. The method of claim 26, wherein calculating the descriptor comprises calculating a series of values of the descriptor for a plurality of time points, in each of the windows.

30. A method of analyzing operation of an integrated circuit on a chip, comprising:
providing a test input to a tested integrated circuit on a chip, repeatedly for a plurality of operation rounds;
sampling signals from a plurality of internal lines of the tested integrated circuit, for the plurality of operation rounds;
generating by a signature circuit on the chip, respective signatures for the plurality of internal lines;
verifying, by the signature circuit, that the signatures of the plurality of internal lines are the same for the plurality of operation rounds; and
exporting from the chip in each operation round, the signals of one or more of the internal lines, but fewer than all the sampled lines.

31. The method of claim 30, wherein sampling the signals comprises sampling at a rate at least equal to the operation rate of the chip for the sampled signals.

32. The method of claim 30, comprising receiving the exported signals of the plurality of operation rounds by a computer and displaying the signals as if they were received from a single operation round.

33. The method of claim 30, comprising exporting the test input through a path used for exporting non-intrusively collected data, in a preliminary operation round, and wherein providing the test input to the tested integrated circuit comprises providing the data exported through the path used for exporting non-intrusively collected data.

34. The method of claim 30, wherein the signatures comprise a cyclically redundancy check code or a checksum.

35. A method of generating a chip with a tested circuit and an embedded agent for non-intrusive export of internal signals of the tested chip, comprising:
providing a design of the tested circuit;
providing a design of the embedded agent;
selecting locations on the chip for the tested circuit and the embedded agent in a manner which reduces interference of the embedded agent to the operation of the tested circuit;
designing a line connecting a sampling point in the tested circuit to a collector of the embedded agent, the line including a cascade of one or more asynchronous gates which add a delay to the line, such that signals sampled at the sampling point reach the collector a predetermined number of clock cycles after their sampling; and
generating a chip with the provided designs of the tested circuit and embedded agent in the selected locations and with the designed line.

36. The method of claim 35, wherein the selected location of the embedded agent is separate from the tested circuit, such that elements of the embedded agent are not located between elements of the tested circuit.

37. The method of claim 36, wherein the designed line does not include synchronous elements between the sampling point and the collector in the embedded agent.

38. The method of claim 35, wherein the cascade of asynchronous gates includes NOT gates.

39. The method of claim 35, wherein the cascade of asynchronous gates includes a plurality of gates.
